(19) United States
(12) Patent Application Publication
(10) Pub. No.: US 2025/0253269 A1
(43) Pub. Date: Aug. 7, 2025

(54) MEMORY MODULE AND METHOD OF MANUFACTURING THE MEMORY MODULE

(71) Applicant: Samsung Electronics Co., Ltd., Suwon-si (KR)

(72) Inventors: Doyoung JUNG, Suwon-si (KR); Jinkyu YANG, Suwon-si (KR); Jaechan LEE, Suwon-si (KR)

(73) Assignee: Samsung Electronics Co., Ltd., Suwon-si (KR)

(21) Appl. No.: 19/039,265

(22) Filed: Jan. 28, 2025

(30) Foreign Application Priority Data
Feb. 1, 2024 (KR) 10-2024-0015909

(51) Int. Cl. H01L 23/62; H01L 23/00; H01L 23/538; H01L 25/16; H10B 80/00; H10D 80/30

(52) U.S. Cl. CPC H01L 23/62; H01L 23/5386; H01L 24/16; H01L 25/16; H10B 80/00; H01L 24/97; H01L 2224/16227; H01L 2224/97; H01L 2924/1431; H10D 80/30

(57) ABSTRACT

A memory module may include a module substrate including first substrate pads and an insertion portion that has a module power terminal on a first substrate side portion of the module substrate; at least one semiconductor device on the module substrate and including chip pads electrically connected to the first substrate pads; substrate wirings including a first power connection wiring that electrically connects the module power terminal and the at least one semiconductor device; test wirings including a power test wiring that is branched from the first power connection wiring and has an end portion exposed from a second substrate side portion, the second substrate side portion adjacent the first substrate side portion; and a short protection structure on the module substrate, the short protection structure being adjacent the second substrate side portion, in the power test wiring, and configured to selectively block electrical flow through the power test wiring.

### PRIORITY STATEMENT

This application claims priority under 35 U.S.C. § 119 to Korean Patent Application No. 10-2024-0015909, filed on Feb. 1, 2024 in the Korean Intellectual Property Office (KIPO), the contents of which are herein incorporated by reference in their entirety.

### BACKGROUND

### 1. Field

At least some example embodiments relate to a memory module and/or to methods of manufacturing the memory module. For example, at least some example embodiments relate to a memory module including a short protection structure and/or to methods of manufacturing the same.

### 2. Description of the Related Art

In manufacturing a solid state drive (SSD) device including, for example, one or more semiconductor devices such as DRAM, NAND, controller, etc., a test process may be performed to check mounting conditions of the semiconductor devices in the SSD. In such a case, with respect to efficiency of test processes, it may be advantageous to perform test processes on a module array that includes a plurality of SSD devices. Accordingly, the module array may include test wirings that are electrically connected to the plurality of SSD devices. However, the test wirings may be exposed to the outside after an individualization process is performed to separate the plurality of SSD devices into individual SSD devices. Accordingly, there may be a problem that the exposed test wirings are incorrectly and/or insufficiently connected to an external apparatus, and a short circuit may occur in the SSD device. For example, in case that a power wiring among the test wirings is in contact with a ground of the external apparatus, a short circuit may occur in the SSD device.

### SUMMARY

Some example embodiments relate to a memory module for preventing or reducing the likelihood and/or magnitude of short circuits related to an external device.

Some example embodiments relate to methods of manufacturing the memory module.

According to some example embodiments, a memory module may include a module substrate including a plurality of first substrate pads, the module substrate having an insertion portion that has a module power terminal on a first substrate side portion of the module substrate; at least one semiconductor device on the module substrate and including a plurality of chip pads electrically connected to the plurality of first substrate pads; a plurality of substrate wirings including a first power connection wiring that electrically connects between the module power terminal and the at least one semiconductor device; a plurality of test wirings including a power test wiring that is branched from the first power connection wiring and has an end portion exposed from a second substrate side portion, the second substrate side portion adjacent to the first substrate side portion; and a short protection structure on the module substrate adjacent the second substrate side portion, the short protection structure being adjacent to the second substrate side portion, in the power test wiring, and configured to selectively block electrical flow through the power test wiring.

According to some example embodiments, a memory module may include a module substrate including a plurality of first substrate pads, the module substrate that has an insertion portion, the insertion portion having a module power terminal and a module ground terminal on a first substrate side portion of the module substrate; at least one semiconductor device on the module substrate and including a plurality of chip pads electrically connected to the plurality of first substrate pads; a plurality of substrate wirings including a first power connection and a ground connection wiring, the first power connection wiring electrically connecting the module power terminal and the at least one semiconductor device, the a ground connection wiring electrically connecting the module ground terminal and the at least one semiconductor device; a plurality of test wirings including a power test wiring and a ground test wiring, wherein the power test wiring is branched from the first power connection wiring and has a first end portion exposed from a second substrate side portion adjacent the first substrate side portion, wherein the ground test wiring is branched from the ground connection wiring and has a second end portion exposed from the second substrate side portion; and a short protection structure on the module substrate, the short protection structure being adjacent the second substrate side portion, disposed in the power test wring, and configured to selectively block electrical flow through the power test wiring.

According to some example embodiments, a memory module may include a module substrate including a plurality of first substrate pads and a plurality of second substrate pads, the module substrate having an insertion portion that has a module power terminal on a first substrate side portion of the module substrate; a first semiconductor device including a plurality of first chip pads and a plurality of first conductive connection members and mounted on the module substrate by the plurality of first conductive connection members, the plurality of first connection members respectively located between the plurality of first substrate pads and the plurality of first chip pads; a second semiconductor device including a plurality of second chip pads and a plurality of second conductive connection members and mounted on the module substrate by the plurality of second conductive connection members, the plurality of second conductive connection members respectively located between the plurality of second substrate pads and the plurality of second chip pads; a plurality of substrate wirings including a first power connection wiring and a second power connection wiring, the first power connection wiring electrically connecting the module power terminal and the first semiconductor device, the second power connection wiring electrically connecting the first semiconductor device and the second semiconductor device; a plurality of test wirings including a power test wiring that is branched from the first power connection wiring and has an end portion exposed from a second substrate side portion, the second substrate side portion adjacent the first substrate side portion; and a short protection structure disposed on the module substrate, the short protection structure being adjacent the second substrate side portion, in the power test wring, and configured to selectively block electrical flow through the power test wiring.

According to some example embodiments, a memory module may include a module substrate having an insertion portion that has a module power terminal on a first substrate side portion, at least one semiconductor device mounted on the module substrate, a plurality of substrate wirings including a first power connection wiring that electrically connects the at least one semiconductor device and the module power terminal, and test wirings including a power test wiring that is branched from the first power connection wiring and has an end portion exposed from a second substrate side portion, the second substrate side portion adjacent to the first substrate side portion.

The module substrate may include a short protection structure, the short protection structure adjacent to the second substrate side portion, in the power test wiring, and configured to block electrical flow through the power test wiring.

Accordingly, the memory module before being individualized may receive power from a test device through the power test wiring. In addition, or alternatively, by including the short protection structure, the memory module after being individualized may allow for prevention or reduced likelihood and/or magnitude of short circuits of the memory module when an external device is connected to the power test wiring.

### BRIEF DESCRIPTION OF THE DRAWINGS

FIG. 1 is a plan view illustrating a memory module in accordance with some example embodiments.

FIG. 2 is a cross-sectional view taken along the line C1-C1′ in FIG. 1.

FIG. 3 is a cross-sectional view taken along the line C2-C2′ in FIG. 1.

FIG. 4 is a cross-sectional view taken along the line C3-C3′ in FIG. 1.

FIG. 5 is a plan view illustrating a memory module in accordance with some example embodiments.

FIGS. 6 to 15 are views illustrating a method of manufacturing a memory module in accordance with some example embodiments.

FIG. 16 is a plan view illustrating a memory module in accordance with some example embodiments.

### DETAILED DESCRIPTION OF EXAMPLE EMBODIMENTS

Hereinafter, some example embodiments will be explained in detail with reference to the accompanying drawings.

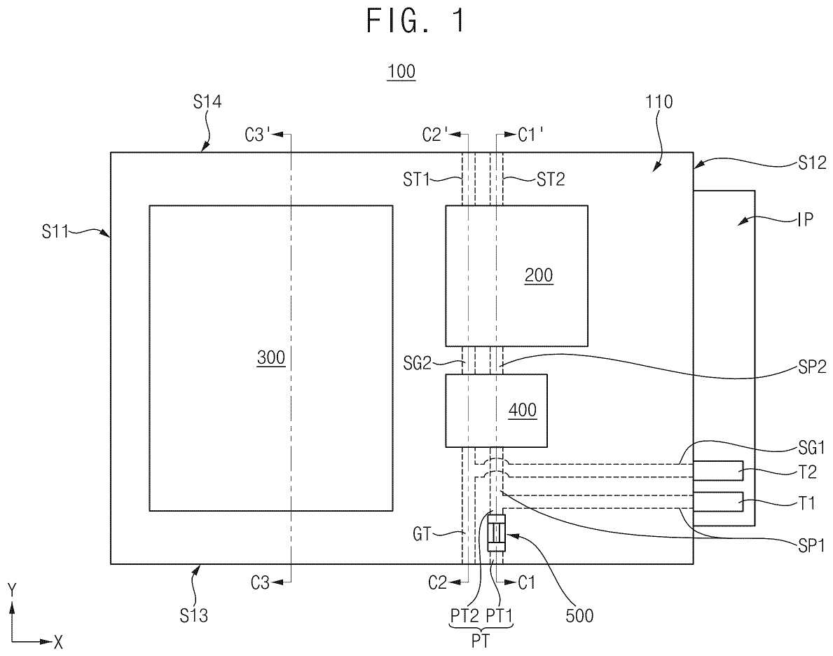

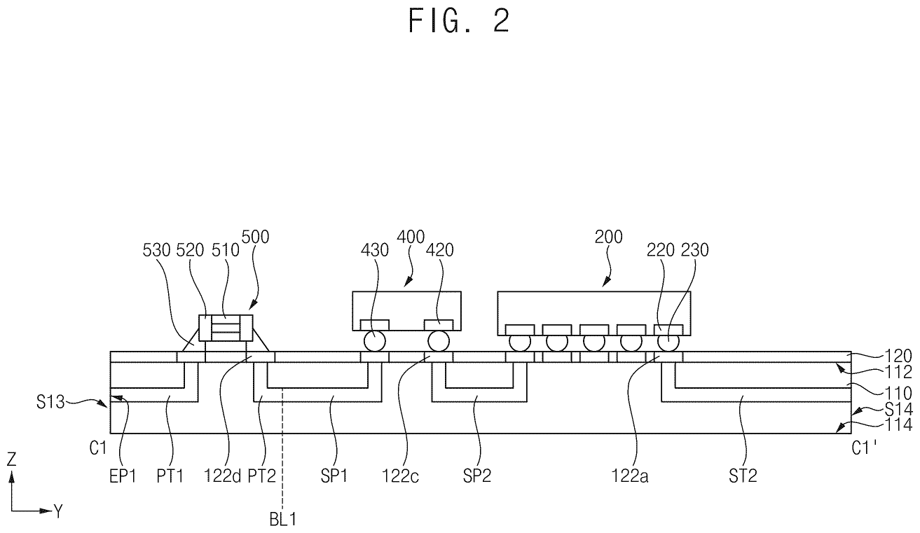

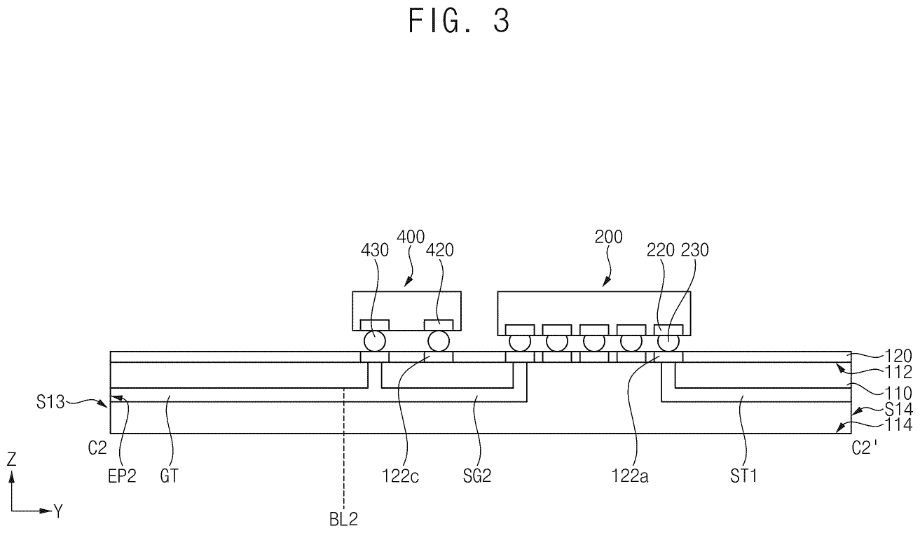

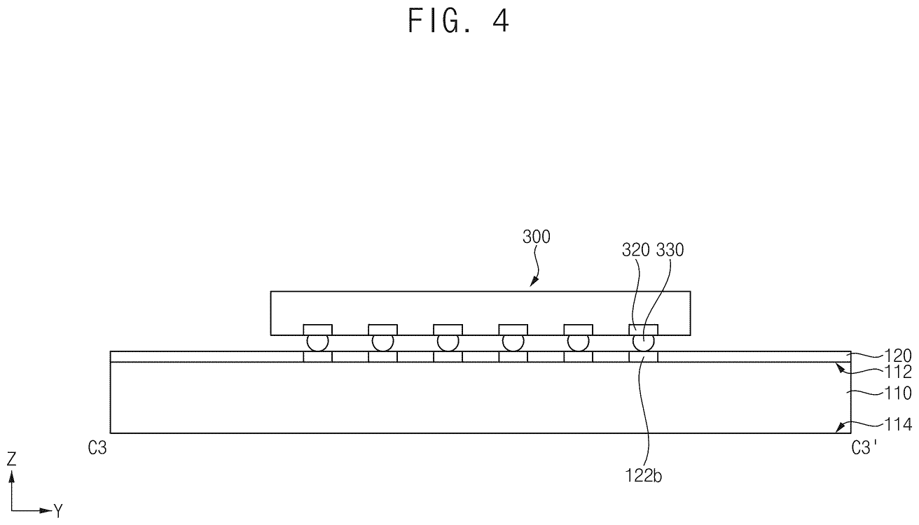

FIG. 1 is a plan view illustrating a memory module in accordance with some example embodiments. FIG. 2 is a cross-sectional view taken along the line C1-C1′ in FIG. 1. FIG. 3 is a cross-sectional view taken along the line C2-C2′ in FIG. 1. FIG. 4 is a cross-sectional view taken along the line C3-C3′ in FIG. 1.

Referring to FIGS. 1 to 4, a memory module 100 may include a module substrate 110, first, second and third semiconductor devices 200, 300 and 400 mounted on the module substrate 110, and a short protection structure 500 mounted on the module substrate to be spaced apart from the first to third semiconductor devices 200, 300, and 400. Additionally, the memory module 100 may further include first, second, third and fourth conductive connection members 230, 330, 430, and 530. Further, the memory module 100 may further include a plurality of test wirings TL and a plurality of substrate wirings SL.

For example, the memory module may be an electronic device such as, for example, a solid-state drive (SSD) device as a storage device. For example, the memory module may include a plurality of semiconductor devices including, for example, one or more of NAND, DRAM, controller, etc. Although the figures illustrate that the memory module may include the first to third semiconductor devices, the present inventive concepts are not limited thereto, and the number, arrangement, and size of the semiconductor devices in the memory module may be varied.

In some example embodiments, the module substrate 110 may have a first surface 112 and a second surface 114 opposite to the first surface 112. Additionally, the module substrate 110 may have a plurality of substrate pads 122 on the first surface 112. The module substrate 110 may additionally include, for example, a substrate insulation layer 120 that covers the first surface 112 and exposes (for example, at least partially exposes) the plurality of substrate pads 122.

The module substrate 110 may have first to fourth substrate side portions S11, S12, S13, and S14. For example, the third substrate side portion S13 and the fourth substrate side portion S14 may extend in a first direction (X direction) to face each other, and the first substrate side portion S11 and the second substrate side portion S12 may extend in a second direction (Y direction) orthogonal to the first direction (X direction) to face each other.

The module substrate 110 may include an insertion portion IP provided at the second substrate side portion S12 to serve as a connector with an external device. The insertion portion IP may include, for example, a module power terminal T1 and a module ground terminal T2. For example, the insertion portion may be a portion configured to connect the memory module to the external device. The module power terminal and the module ground terminal may be portions mechanically and/or electrically connected with power and ground of the external device, respectively.

The plurality of substrate pads 122 may include a plurality of first to fourth substrate pads 122a, 122b, 122c, and 122d. For example, although not illustrated in the figures, the module substrate may include a plurality of internal wirings for transmitting electrical signals. The plurality of internal wirings may be electrically connected to any or each of the plurality of first to fourth substrate pads 122a, 122b, 122c, and 122d.

In some example embodiments, the first semiconductor device 200 may be mounted on the module substrate 110 and may have a plurality of first chip pads 220 on a front surface thereof. In addition, the first semiconductor device 200 may include a plurality of first conductive connection members 230. For example, the first semiconductor device 200 may be mounted on the module substrate 110 via the plurality of first conductive connection members 230 that are interposed between the plurality of first substrate pads 122a and the plurality of first chip pads 220, respectively.

For example, the first semiconductor device may include, for example, one or more logic chips. The logic chip(s) may be or include a controller configured to control memory elements. The first semiconductor device may include, for example, at least one a processor chip such as an application processor (AP) and/or at least an ASIC as a host, such as a CPU, GPU, SOC, etc., but example embodiments are not limited thereto.

In some example embodiments, the second semiconductor device 300 may be mounted on the module substrate 110 to be spaced apart from the first semiconductor device 200 in the first direction (X direction). The second semiconductor device 300 may have a plurality of second chip pads 320 on a front surface thereof. The second semiconductor device 300 may include a plurality of second conductive connection members 330. For example, the second semiconductor device 300 may be mounted on the module substrate 110 via the plurality of second conductive connection members 330 that are provided between the plurality of second substrate pads 122b and the plurality of second chip pads 320, respectively.

For example, the second semiconductor device may include non-volatile memory devices such as, for example, flash memory devices, PRAM devices, MRAM devices, RRAM devices, etc. and/or volatile memory devices such as SRAM devices, DRAM devices, etc., but example embodiments are not limited thereto.

In some example embodiments, the third semiconductor device 400 may be mounted on the module substrate 110 to be spaced apart from the first semiconductor device 200 in the second direction (Y direction). The third semiconductor device 400 may have a plurality of third chip pads 420 on a front surface thereof. The third semiconductor device 400 may include a plurality of third conductive connection members 430. For example, the third semiconductor device 400 may be mounted on the module substrate 110 via the plurality of third conductive connection members 430 that are interposed between the plurality of third substrate pads 122c and the plurality of third chip pads 420, respectively.

For example, the third semiconductor device may include, for example, a power management integrated circuit (PMIC). The PMIC may be a semiconductor device configured to distribute an electrical signal having, for example, a voltage (for example, a constant voltage) to match a drive voltage of any or each of a plurality of semiconductor devices in the memory module. The electrical signal may be, for example, a power signal from the external apparatus into which the memory module is inserted, but example embodiments are not limited thereto.

In some example embodiments, the short protection structure 500 may include a body portion 510 and a connection portion 520. Additionally, the short protection structure 500 may include a plurality of fourth conductive connection members 530 that are provided between the connection portion 520 and the plurality of fourth substrate pads 122d. For example, the short protection structure may be a fuse configured to prevent or hinder current from flowing through the short protection structure when current greater than a certain (for example, desired, or alternatively, predetermined or threshold) value flows into the short protection structure. (Accordingly, short protection structure 500 may be called, for example, “short prevention structure” or “short reduction structure,” although the function of feature 500 should not be understood as limited thereto.)

For example, the short protection structure 500 may be disposed on the module substrate 110 adjacent to the first substrate side portion S13. The short protection structure 500 may, for example, block or hinder electrical connection of the first substrate side portion S13 and an external device to which the memory module is connected.

For example, the body portion 510 may include a central portion having an inner wiring through which current may flow and an outer portion surrounding the central portion. The central portion may include, for example, a metallic material, but example embodiments are not limited thereto. The outer portion may include, for example, a ceramic material, but example embodiments are not limited thereto. In case that a current greater than a certain (for example, desired, or alternatively, predetermined or threshold) value flows into the central portion, the inner wiring of the center portion may be melted such that the short protection structure 500 becomes an open circuit. For example, the open circuit may be a circuit through which current cannot flow or substantially flow.

In some example embodiments, the plurality of substrate wirings SL may include, for example, a plurality of ground connection wirings SG and/or a plurality of power connection wirings SP. For example, the plurality of substrate wirings may be or include a plurality of wirings that are provided in the module substrate and are configured to electrically connect the first semiconductor device 200 and the third semiconductor device 300 to the external device in which the insertion portions IP of the module substrate 110 are mounted.

The plurality of power connection wirings SP may include a first power connection wiring SP1 that electrically connects the module power terminal T1 to the third semiconductor device 400 and a second power connection wiring SP2 that electrically connects the third semiconductor device 400 to the first semiconductor device 200. For example, the plurality of power connection wirings may be wirings configured to be electrically connected to power terminals of the external device. The power terminals may be terminals configured to apply power to circuits of the memory module. The external device may be a test device configured to test a module array including, for example, a plurality of memory modules or a PCB on which the individualized memory module 100 is mounted via the insertion portion IP of the module substrate 110.

For example, the first power connection wiring SP1 may be a wiring configured to transmit a first electrical signal that is introduced from the module power terminal T1 to the third semiconductor device 300. The second power connection wiring SP2 may be a wiring configured to transmit a second electrical signal that is introduced from the third semiconductor device 300 to the first semiconductor device 200. For example, after the first electrical signal are transmitted to the third semiconductor device 300, the first electrical signal may be converted into electrical signals having corresponding voltages that are matched with semiconductor devices, and the electrical signals may be respectively transmitted to the semiconductor devices in the memory module 100.

For example, the first electrical signal may have a first current and the second electrical signal may have a second current. For example, the first current may be smaller than the second current. For example, the short protection structure 500 may be or include a fuse that opens in case that a current greater than the first current flows into the fuse.

The plurality of ground connection wirings SG may include a first ground connection wiring SG1 that electrically connects the module ground terminal T2 to the third semiconductor device 400 and a second ground connection wiring SG2 that electrically connects the third semiconductor device 400 to the first semiconductor device 200. For example, the plurality of ground connection wirings may be wirings configured to be electrically connected to ground terminals of the external device, respectively. The ground terminal may be, for example, a ground terminal that serves as a reference for voltage measurements in a circuit. The external device may, for example, be a test device configured to test the module array including a plurality of memory modules or a PCB on which the individualized memory module 100 is mounted via the insertion portion IP of the module substrate 110, but example embodiments are not limited thereto.

For example, the first ground connection wiring SG1 may be a wiring configured to transmit a third electrical signal, which is introduced from the third semiconductor device 300, to the module ground terminal T2. The second ground connection wiring SG2 may be a wiring configured to transmit a fourth electrical signal, which is introduced from the first semiconductor device 200, to the third semiconductor device 300.

In some example embodiments, the plurality of test wirings TL may include a plurality of signal test wirings ST, a plurality of power test wirings PT, and a ground test wiring GT. For example, the plurality of test wirings may be a plurality of wirings that are provided inside the module substrate 110 and are configured to transmit a test signal, which may be introduced during a test process, to the module substrate 110. For example, the test process may be a process for checking a mounting condition of electronic devices mounted in the memory module 100. The test process may be, for example, performed simultaneously on a plurality of memory modules as a form of the module array, but example embodiments are not limited thereto.

The plurality of signal test wirings ST may include a first signal test wiring ST1 and a second signal test wiring ST2 that are disposed adjacent to the fourth substrate side portion S14 of the module substrate 110 such that each of the first signal test wiring ST1 and the second signal test wiring ST2 has an end portion exposed from the fourth substrate side portion S14.

For example, the first signal test wiring ST1 and the second signal test wiring ST2 may be provided in the module substrate 110 and extend from the fourth substrate side portion S14 of the module substrate 110 to the first semiconductor device 200. Each of the first signal test wiring ST1 and the second signal test wiring ST2 may be electrically connected with a portion of the plurality of first substrate pads 122a which is electrically connected with the first semiconductor device 200. For example, the first signal test wiring may be or include a wiring configured to apply the test signal from the test device to the first semiconductor device. Further, for example, the second signal test wiring may be or include a wiring configured to withdraw the test signal from the first semiconductor device to the test device, but example embodiments are not limited thereto.

The plurality of power test wirings PT may include a first power test wiring PT1 and a second power test wiring PT2 electrically connected to the short protection structure 500, respectively. The first power test wiring PT1 may have a first end portion EPI that is exposed from the third substrate side portion S13. The second power test wiring PT2 may be branched from the first power connection wiring SP1. For example, the plurality of power test wiring may be or include a wiring configured to transmit a power signal of the test device to the third semiconductor device 400.

For example, the plurality of power test wirings may transmit the power signal of the test device to the third semiconductor device 400 by passing through the short protection structure 500 to merge into the first power connection wiring SP1. The second power test wiring PT2 may be branched from a first branch portion BL1 of the first power connection wiring SP1 to be electrically connected to the fourth substrate pad 122d. Additionally, the first power test wiring PT1 may have the first end portion EP1 exposed from the third substrate side portion S13 and be electrically connected to the fourth substrate pad 122d.

The ground test wiring GT may be branched from the first ground connection wiring SG1 and have a second end portion EP2 exposed from the third substrate side portion S13. For example, the ground test wiring may be a wiring configured to respectively connect the ground terminal of the test device to the first to third semiconductor devices 200, 300 and 400. Although the figures illustrate that the ground test wiring is connected to the first and third semiconductor devices, respectively, the present inventive concepts are not limited thereto. Accordingly, the ground test wiring may be electrically connected to any or each of the semiconductor devices mounted on the module substrate.

For example, the ground test wiring may be merged into the first ground connection wiring SG1 to transmit an electrical signal of the third semiconductor device 400 to the ground terminal of the test device. The ground test wiring may be branched from a second branch portion BL2 of the first ground connection wiring SG1 and have the second end portion EP2 exposed from the third substrate side portion S13.

As described above, the memory module 100 may include the module substrate 110, the first, second, and third semiconductor devices 200, 300, 400 mounted on the module substrate 110, and the short protection structure 500 mounted on the module substrate 110 and spaced apart from the first, second, and third semiconductor devices 200, 300, 400. Additionally, the memory module 100 may further include the plurality of first, second, third, and fourth conductive connection members 230, 330, 430, 530. Further, the memory module 100 may include the plurality of test wirings TL and the plurality of substrate wirings SL.

The module substrate 110 may include the insertion portion IP having the module power terminal T1. The plurality of substrate wirings SL may include the first power connection wiring SP1 that is configured to electrically connect the module power terminal T1 and the third semiconductor device 300. The plurality of test wirings TL may include the plurality of power test wirings PT that is branched from the first power connection wiring SP1 and have the first end portion EP1 exposed from the third side portion S13 of the module substrate 110. The plurality of power test wirings PT may include the first power test wiring PT1 having the first end portion EP1 exposed from the third substrate side portion S13 and electrically connected to the short protection structure 500 and the second power test wiring PT2 branched from the first power connection wiring SP1 to be electrically connected to the short protection structure 500. Further, the short protection structure may be or include the fuse that is configured to block current flowing through the short protection structure when the current greater than a certain (for example, desired, or alternatively, predetermined or threshold) value flows through the short protection structure.

Accordingly, the short protection structure 500 may prevent or hinder an electrical signal, which may be introduced from the module power terminal T1, from flowing to the plurality of power test wirings PT. Accordingly, the short protection structure 500 may prevent or reduce the likelihood and/or magnitude short circuits of the memory module 100 when the external device is connected to the first end portion EP1 of the first power test wiring PT1.

Hereinafter, a memory module according to some example embodiments will be described.

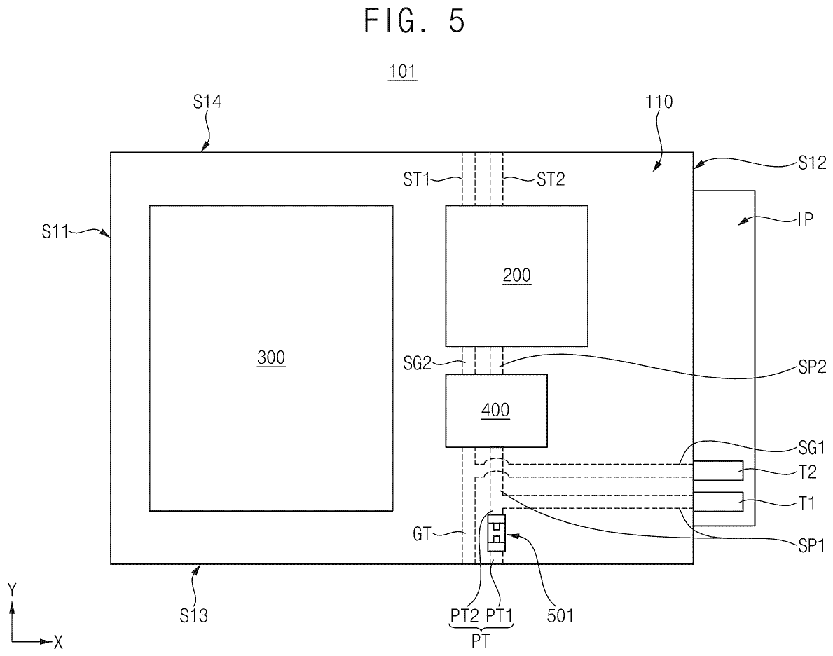

FIG. 5 is a plan view illustrating a memory module in accordance with some example embodiments.

Since the memory module according to some example embodiments is substantially the same as the memory module illustrated in FIGS. 1 to 4 except for the short protection structure 501, identical components may be denoted by the same reference numerals, and 5repeated descriptions of identical components may be omitted.

Referring to FIG. 5, the short protection structure 501 may include a body portion 510 and a connection portion 520. Further, the short protection structure 501 may include a plurality of fourth conductive connection members 530 provided between the connection portion 520 and the plurality of fourth substrate pads 122d. For example, the short protection structure may include a fuse configured to block current which is flows through the short protection structure when current greater than a certain (for example, desired, or alternatively, predetermined or threshold) value flows through the short protection structure.

For example, the short protection structure 501 may be disposed on the module substrate 110 adjacent to the first substrate side portion S13. For example, the short protection structure 500 may block electrical flow from the first substrate side portion S13 to an external device to which the memory module is connected.

For example, the body portion 510 may include a center portion having an inner wiring through which electrical current may flow and an outer portion surrounding the center portion. For example, the inner wiring may include a metallic material, but example embodiments are not limited thereto. Further, the outer portion may include a ceramic material, but example embodiments are not limited thereto. For example, the inner wiring may be or become an open circuit by applying overcurrent. For example, the open may be a circuit through which current cannot flow.

Accordingly, the short protection structure 501 may block (for example, substantially block) an electrical signal, which is introduced from the module power terminal T1, from flowing to the plurality of power test wirings PT. Thus, the memory module 101 may prevent or reduce the likelihood and/or magnitude of short circuits of the memory module by the short protection structure 501 when the external device is connected to the plurality of power test wirings PT.

Hereinafter, a method of manufacturing a memory module in accordance with some example embodiments will be described.

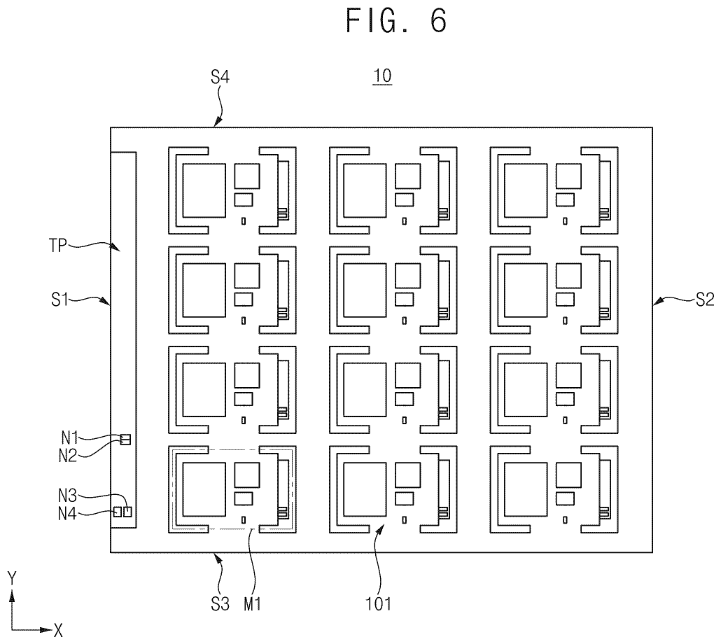

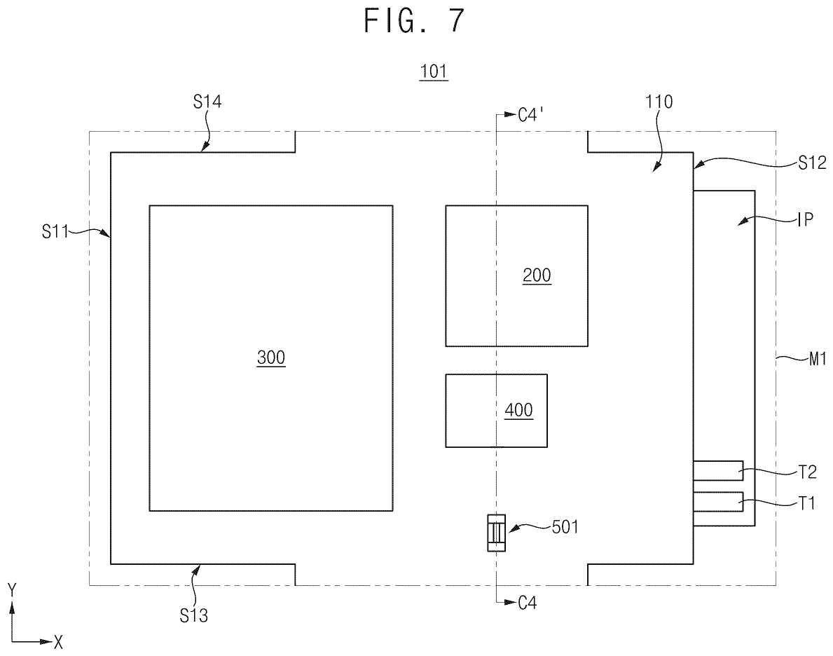

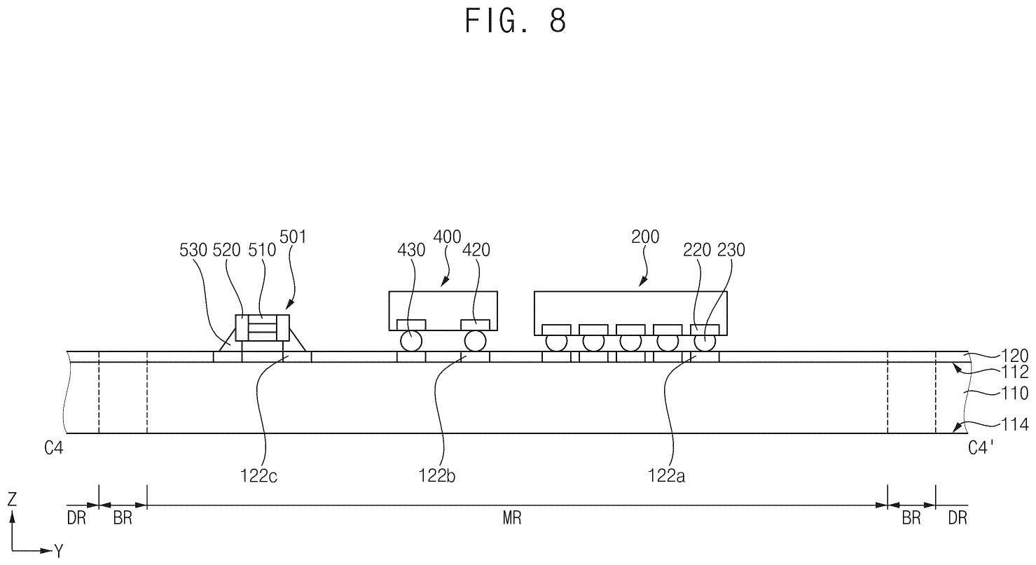

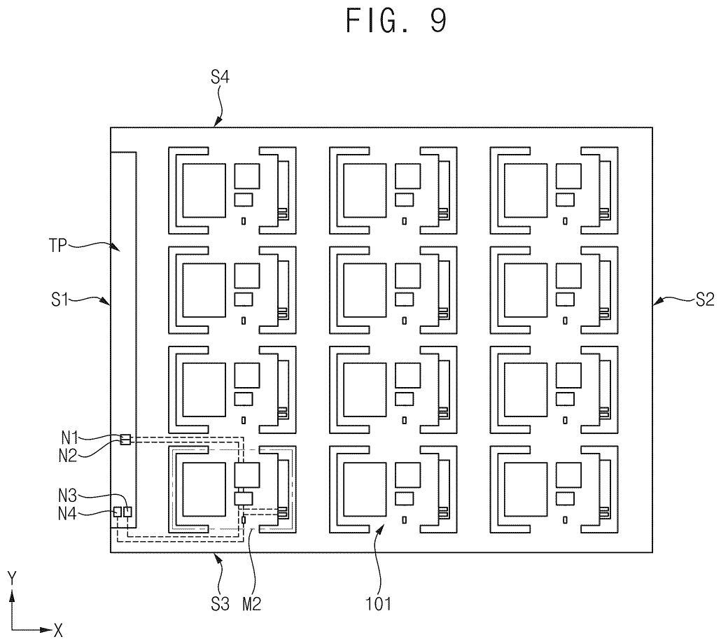

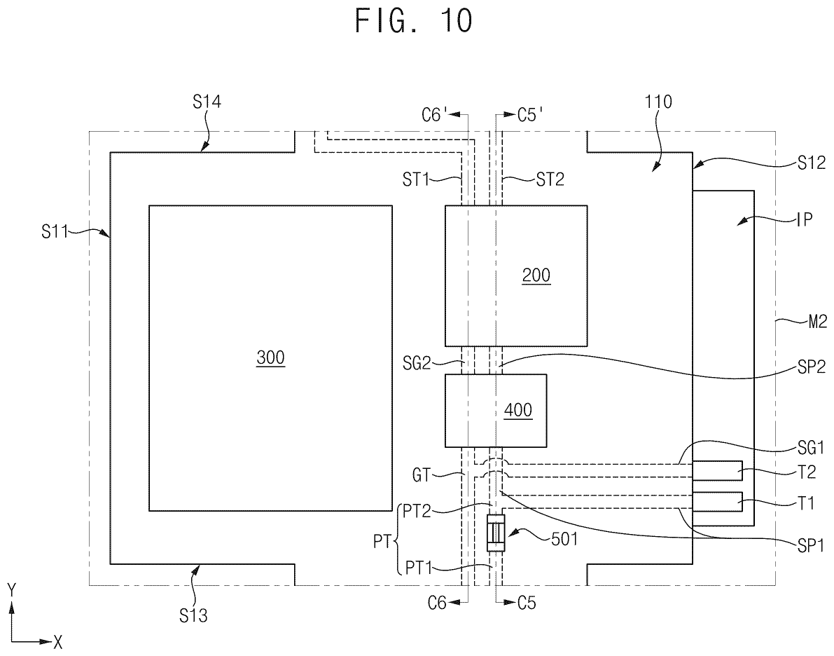

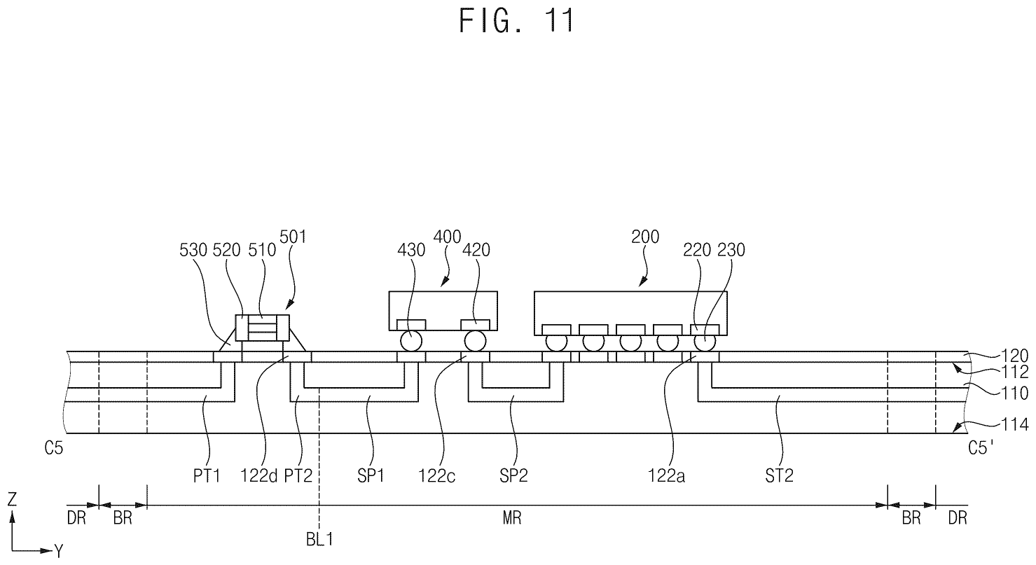

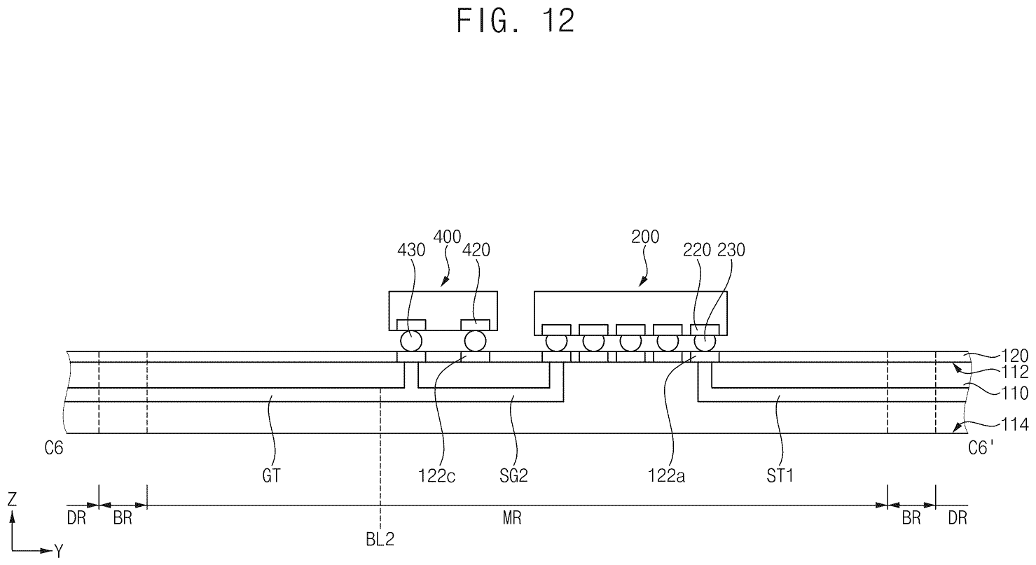

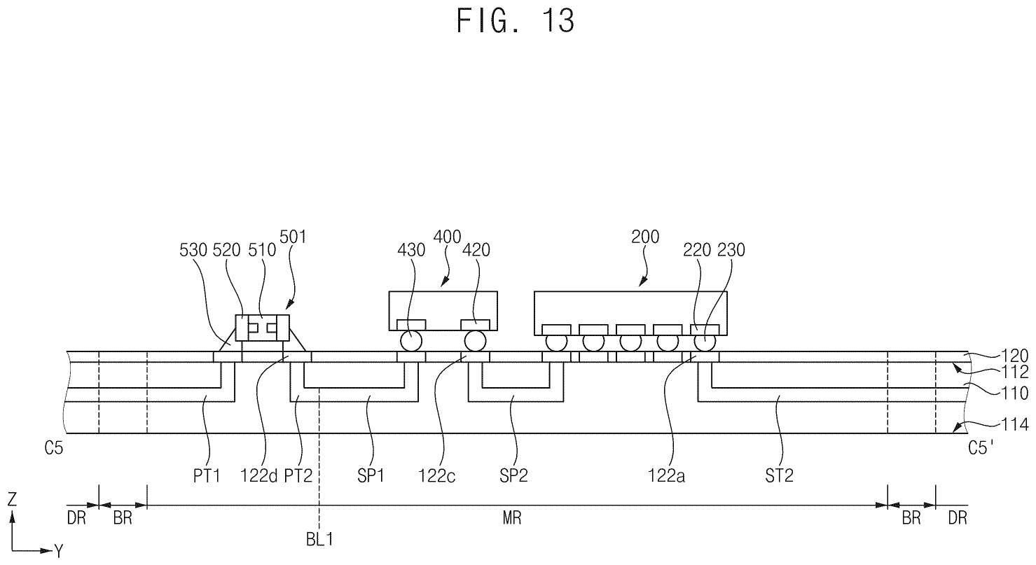

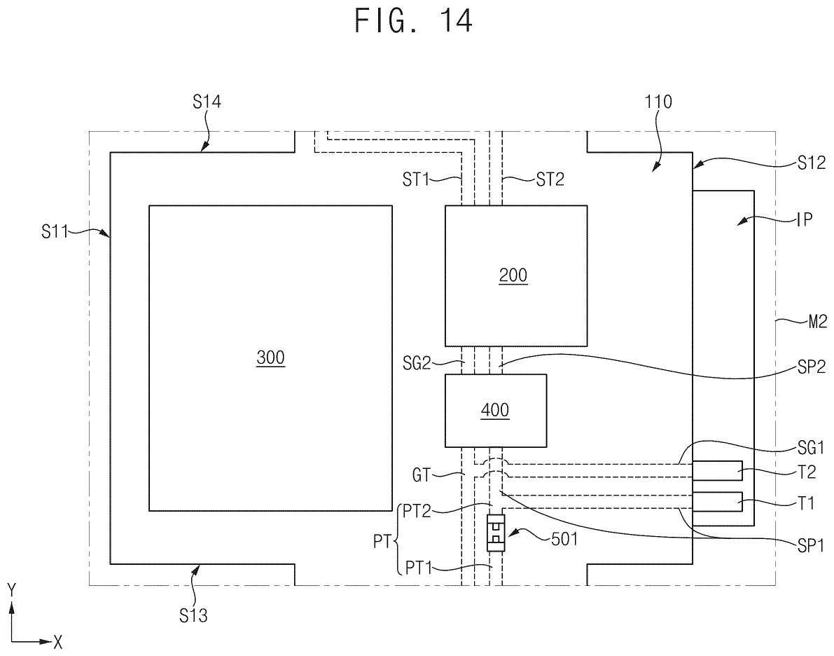

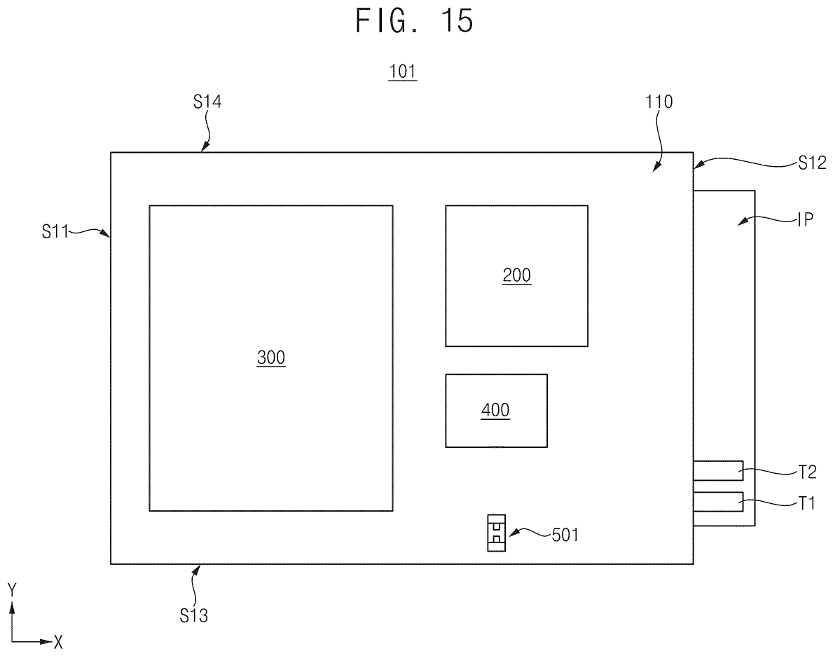

FIG. 6 is a plan view illustrating a module array in accordance with example embodiment. FIG. 7 is an enlarged plan view illustrating portion ‘M1’ in FIG. 6. FIG. 8 is a cross-sectional view taken along the line C4-C4′ in FIG. 7. FIG. 9 is a plan view illustrating that the module array in FIG. 6 is tested. FIG. 10 is an enlarged plan view illustrating portion ‘M2’ in FIG. 9. FIG. 11 is a cross-sectional view taken along the line C5-C5′ in FIG. 10. FIG. 12 is a cross-sectional view taken along the line C6-C6′ in FIG. 10. FIG. 13 is a cross-sectional view illustrating that the short protection structure in accordance with example embodiment open. FIG. 14 is an enlarged plan view illustrating that a memory module including the short protection structure in FIG. 13. FIG. 15 is a plan view illustrating a memory module in accordance with example embodiment.

Referring to FIGS. 6 to 8, a module array 10 including a plurality of memory modules may be provided.

Since the memory module is substantially the same as the memory module 101 illustrated in FIG. 5, identical components are denoted by the same reference numerals and repeated descriptions of identical components are omitted.

In some example embodiments, the module array 10 may include a plurality of module regions MR arranged in rows and columns, a dummy region DR on which no electronics are mounted, and a plurality of bridge regions BR connecting the dummy region DR to the module regions MR. Additionally, the module array 10 may further include a test portion TP configured to connect the module array 10 to a test apparatus.

A memory module 101 may be provided on each of the module regions MR of the module array 10. Further, the module array 10 may have first, second, third, and fourth side portions S1, S2, S3, and S4. For example, the third side portion S3 and the fourth side portion S4 may extend in a first direction (X direction) facing each other. Further, the first side portion S1 and the second side portion S2 may extend in a second direction (Y direction) facing each other.

For example, the test portion TP may extend in the second direction (Y direction) to be adjacent to the first side portion S1.

The test portion TP may include a plurality of test terminals. The plurality of test terminals may be configured to be electrically connected to each of memory modules via a plurality of wirings. For example, the test portion TP may include first, second, third, and fourth test terminals N1, N2, N3, and N4, but example embodiments are not limited thereto. For example, the first test terminal and the second test terminal may be respectively connected with a plurality of signal test wirings ST of the memory module 101. Further, the third test terminal may be connected to a plurality of ground test wirings GT of the memory module 101. Further, the fourth test terminal may be connected to a plurality of power test wirings PT of the memory module 101.

Referring to FIGS. 9 to 12, a test process may be performed on each of the plurality of memory modules included in the module array 10 by using the test apparatus. For example, the test process may a process for checking that the electronic devices are correctly mounted on each of the plurality of memory modules, but example embodiments are not limited thereto.

For example, test signals from the test device may be transmitted to each of the memory modules via the first signal test wiring ST1 of the memory module 101. Further, after the test process is completed, the test signals may be returned to the test device via the second signal test wiring ST2 of the memory module 101.

For example, the electronic devices 200, 300, 400 and 500 in the memory module 101 may be connected to the ground terminal of the test device via the ground test wiring GT.

For example, a power signal of the test device may be transmitted to the short protection structure 501 via the first power test wiring PT1 of the memory module 101. Further, the power signal may be transmitted from the short protection structure 501 to the third semiconductor device 400 via the second power test wiring PT2 and the first power connection wiring SP1. Further, the power signal may be transmitted from the third semiconductor device 400 to the first semiconductor device 200 via the second power connection wiring SP2. For example, the power signal of the test device, which is transmitted from the test device to the third semiconductor device, may have a fifth electrical signal.

Referring to FIGS. 13 and 14, the short protection structure may become an open circuit by introducing an electrical signal, which has a current greater than a certain (for example, desired, or alternatively, predetermined or threshold) value, into the module array 10. For example, the open circuit may be a circuit where current cannot flow through the circuit because the current is blocked.

For example, by using the test device, a sixth electrical signal may be transmitted to each of the memory modules 101 included in the module array 10. For example, the sixth electrical signal may have a sixth current greater than the fifth current of the fifth electrical signal. For example, the sixth current of the sixth electrical signal may have a strength which is capable of making the short protection structure as fuse 501 the open circuit.

Accordingly, the current, which is transmitted through the plurality of power test wirings PT electrically connected to the short protection structure 501, may be blocked or substantially blocked.

Referring to FIG. 15, the memory module 101 may be completed by individualizing the plurality of memory modules of the module array 10.

For example, each of the bridge regions BR of the module array 10 may be cut by using a blade to individualize the memory module 101.

Hereinafter, a memory module in accordance with an example embodiment will be described.

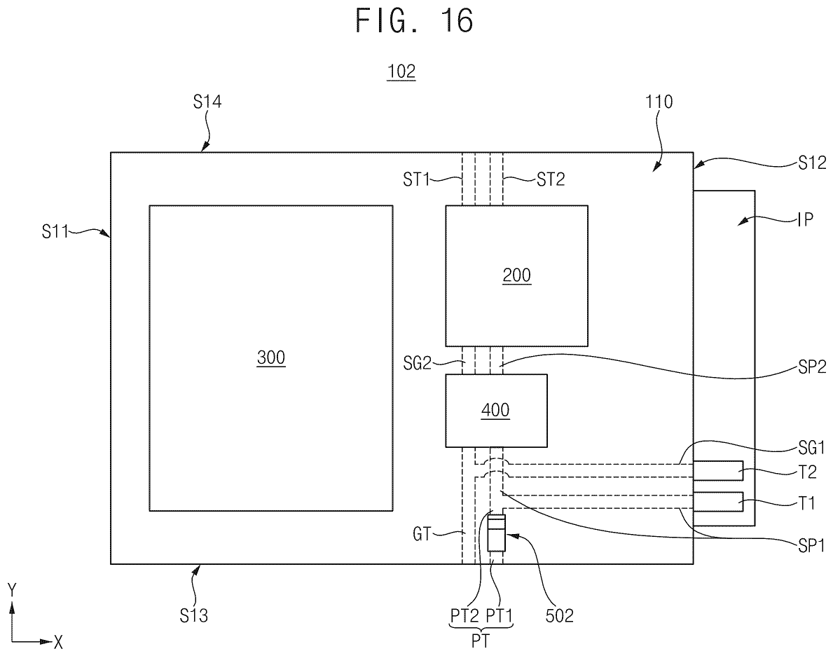

FIG. 16 is a plan view illustrating a memory module in accordance with some example embodiments.

Since the memory module in accordance with some example embodiments may be the same or substantially the same as the memory module illustrated in FIGS. 1 to 4 except for the short protection structure 502, such similar components are denoted by the same or similar reference numerals and repeated descriptions of such components are omitted.

Referring to FIG. 16, the short protection structure 502 may include a body portion 510 and a connection portion 520. Additionally, the short protection structure 500 may include a plurality of fourth conductive connection members 530 that are provided between the connection portion 520 and the plurality of fourth substrate pads 122d. For example, the short protection structure 502 may be disposed on the module substrate 110 to be adjacent to the first substrate side portion S13.

For example, the short protection structure may include a diode configured to allow a current along a certain (for example, desired, or alternatively, predetermined) direction to flow therethrough. For example, the short protection structure 502 may allow electrical signals to pass from an external device to the short protection structure 502. In contrast, the short protection structure 502 may block electrical signals from the external device to the short protection structure 502.

Accordingly, the short protection structure 502 may block an electrical signal, which is introduced from the module power terminal T1, from flowing to the plurality of power test wirings PT. Accordingly, the memory module 100 may prevent or hinder short circuit of the memory module from occurring by the short protection structure 502 when the external device is connected to the plurality of power test wirings PT.

The memory module may include logic devices such as, for example, central processing units (CPUs), main processing units (MPUs), or application processors (APs), and/or the like, and/or volatile memory devices such as, for example, DRAM devices, HBM devices, and/or non-volatile memory devices such as flash memory devices, PRAM devices, MRAM devices, ReRAM devices, and/or the like, but example embodiments are not limited thereto.

The foregoing is illustrative of some example embodiments of inventive concepts and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the spirit and scope of example embodiments as defined in the claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FGPA), a System-on-Chip (SoC), a programmable logic unit, a microprocessor, application-specific integrated circuit (ASIC), etc.

What is claimed is:

1. A memory module, comprising:
a module substrate including a plurality of first substrate pads, the module substrate having an insertion portion that has a module power terminal on a first substrate side portion of the module substrate;
at least one semiconductor device on the module substrate and including a plurality of chip pads electrically connected to the plurality of first substrate pads;
a plurality of substrate wirings including a first power connection wiring that electrically connects the module power terminal and the at least one semiconductor device;
a plurality of test wirings including a power test wiring that is branched from the first power connection wiring and has an end portion exposed from a second substrate side portion, the second substrate side portion adjacent to the first substrate side portion; and
a short protection structure on the module substrate, the short protection structure being adjacent to the second substrate side portion, in the power test wiring, and configured to selectively block electrical flow through the power test wiring.

2. The memory module of claim 1, wherein the short protection structure includes a fuse having an inner wiring that is configured to open as to block electrical flow therethrough in response to current greater than a certain value flowing thereinto.

3. The memory module of claim 1, wherein the short protection structure includes a fuse having an open inner wiring that is configured to block electrical flow through the power test wiring.

4. The memory module of claim 1, wherein the short protection structure includes a diode that is configured to allow current to flow only in a specific direction therethrough.

5. The memory module of claim 4, wherein the diode is configured to allow current flowing from the second substrate side portion to the at least one semiconductor device and to block current flowing from the module power terminal to the second substrate side portion.

6. The memory module of claim 1, wherein the short protection structure includes
a body portion including an inner wiring that is configured to allow a current below a certain value to flow therethrough;
a pair of connection portions in end portions of the body portion and electrically connected to the inner wiring; and
a plurality of conductive connection members electrically connecting the pair of connection portions to a plurality of second substrate pads of the module substrate.

7. The memory module of claim 6, wherein the power test wiring includes
a first power test wiring including the end portion exposed and electrically connected to portions of the plurality of second substrate pads; and
a second power test wiring branched from the first power connection wiring and electrically connected to portions of the plurality of second substrate pads.

8. The memory module of claim 1, wherein the insertion portion of the module substrate includes a module ground terminal, and the plurality of substrate wirings includes a first ground connection wiring electrically connecting the at least one semiconductor device and the module ground terminal.

9. The memory module of claim 1, wherein the at least one semiconductor device includes
a first semiconductor device on the module substrate and including controller circuits; and
a second semiconductor device on the module substrate and spaced apart from the first semiconductor device and configured to distribute an electrical signal having a corresponding voltage to each semiconductor device.

10. The memory module of claim 9, wherein the plurality of substrate wirings includes a second power connection wiring electrically connecting the first semiconductor device and the second semiconductor device.

11. A memory module, comprising:
a module substrate including a plurality of first substrate pads, the module substrate having an insertion portion, the insertion portion having a module power terminal and a module ground terminal that are on a first substrate side portion of the module substrate;
at least one semiconductor device on the module substrate and including a plurality of chip pads electrically connected to the plurality of first substrate pads;
a plurality of substrate wirings including a first power connection wiring and a ground connection wiring, the first power connection wiring electrically connecting the module power terminal and the at least one semiconductor device, the ground connection wiring electrically connecting the module ground terminal and the at least one semiconductor device;
a plurality of test wirings including a power test wiring and a ground test wiring, wherein the power test wiring is branched from the first power connection wiring and has a first end portion exposed from a second substrate side portion adjacent the first substrate side portion, wherein the ground test wiring is branched from the ground connection wiring and has a second end portion exposed from the second substrate side portion; and
a short protection structure on the module substrate, the short protection structure being adjacent to the second substrate side portion, disposed in the power test wring, and configured to selectively block electrical flow through the power test wiring.

12. The memory module of claim 11, wherein the short protection structure includes a fuse having an inner wiring, the inner wiring configured to open as to block electrical flow therethrough in response to current greater than certain a value flowing thereinto.

13. The memory module of claim 11, wherein the short protection structure includes a fuse having an open inner wiring that is configured to block electrical flow through the power test wiring.

14. The memory module of claim 11, wherein the short protection structure includes a diode that is configured to allow current to flow only in a specific direction therethrough.

15. The memory module of claim 14, wherein the diode is configured to allow current flowing from the second substrate side portion to the at least one semiconductor device and to block current flowing from the module power terminal to the second substrate side portion.

16. The memory module of claim 11, wherein the short protection structure includes
a body portion including an inner wiring that is configured to allow current below a predetermined value to flow therethrough;
a pair of connection portions disposed in end portions of the body portion and electrically connected to the inner wiring; and
a plurality of conductive connection members electrically connecting the pair of connection portions and a plurality of second substrate pads of the module substrate.

17. The memory module of claim 16, wherein the power test wiring includes
a first power test wiring including the first end portion and electrically connected to portions of the plurality of second substrate pads; and
a second power test wiring branched from the first power connection wiring and electrically connected to portions of the plurality of second substrate pads.

18. The memory module of claim 11, wherein the at least one semiconductor device includes
a first semiconductor device on the module substrate and including controller circuits; and
a second semiconductor device on the module substrate, spaced apart from the first semiconductor device, and configured to distribute an electrical signal having a corresponding voltage to each semiconductor device.

19. The memory module of claim 18, wherein the plurality of substrate wirings includes a second power connection wiring electrically connecting the first semiconductor device and the second semiconductor device.

20. A memory module, comprising:
a module substrate including a plurality of first substrate pads and a plurality of second substrate pads, the module substrate having an insertion portion that has a modules power terminal on a first substrate side portion of the module substrate;
a first semiconductor device including a plurality of first chip pads and a plurality of first conductive connection members and mounted on the module substrate by the plurality of first conductive connection members, the plurality of first conductive connection members respectively located between the plurality of first substrate pads and the plurality of first chip pads;
a second semiconductor device including a plurality of second chip pads and a plurality of second conductive connection members and mounted on the module substrate by the plurality of second conductive connection members, the plurality of second conductive connection members respectively located between the plurality of second substrate pads and the plurality of second chip pads;
a plurality of substrate wirings including a first power connection wiring and a second power connection wiring, the first power connection wiring electrically connecting the module power terminal and the first semiconductor device, the second power connection wiring electrically connecting the first semiconductor device and the second semiconductor device;
a plurality of test wirings including a power test wiring that is branched from the first power connection wiring and has an end portion exposed from a second substrate side portion, the second substrate side portion being adjacent to the first substrate side portion; and
a short protection structure on the module substrate, the short protection structure being adjacent to the second substrate side portion, in the power test wring, and configured to selectively block electrical flow through the power test wiring.
